(19) United States
(12) Patent Application Publication
(10) Pub. No.: US 2011/0001158 A1
(43) Pub. Date: Jan. 6, 2011

(54) III-NITRIDE SEMICONDUCTOR LIGHT EMITTING DEVICE

(75) Inventors: Chang Tae Kim, Gyeonggi-do (KR); Tae Hee Lee, Gyeonggi-do (KR); Gi Yeon Nam, Gyeonggi-do (KR)

Correspondence Address: HUSCH BLACKWELL LLP, 190 Carondelet Plaza, Suite 600, ST. LOUIS, MO, 63105, US

(73) Assignee: EPIVALLEY CO., LTD., Gyungbuk (KR)

(21) Appl. No.: 12/865,721

(22) PCT Filed: Sep. 19, 2008
(86) PCT No.: PCT/KR08/05531

§ 371 Date: Jul. 30, 2010

(30) Foreign Application Priority Data
Jan. 31, 2008 (KR) 10-2008-0010273

(51) Int. Cl. H01L 33/32

(52) U.S. Cl. 257/98; 257/E33.025; 257/E33.074

(57) ABSTRACT

The present disclosure relates to a Ill-nitride semiconductor light emitting device, comprising: a substrate with a plurality of protrusions formed thereon, each of the plurality of protrusions having three acute portions and three obtuse portions; and a plurality of Ill-nitride semiconductor layers formed over the substrate and including an active layer for generating light by recombination of electrons and holes.

### TECHNICAL FIELD

The present disclosure relates to a III-nitride semiconductor light emitting device, and more particularly, to a substrate having a protrusion with a side exposed by wet etching, and a III-nitride semiconductor light emitting device using the same.

### BACKGROUND ART

FIG. 1 is a view illustrating one example of a conventional III-nitride semiconductor light emitting device. The III-nitride semiconductor light emitting device includes a substrate 100, a buffer layer 200 grown on the substrate 100, a n-type nitride semiconductor layer 300 grown on the buffer layer 200, an active layer 400 grown on the n-type nitride semiconductor layer 300, a p-type nitride semiconductor layer 500 grown on the active layer 400, a p-side electrode 600 formed on the p-type nitride semiconductor layer 500, a p-side bonding pad 700 formed on the p-side electrode 600, and a n-side electrode 800 formed on the n-type nitride semiconductor layer exposed by mesa-etching the p-type nitride semiconductor layer 500 and the active layer 400.

In the case of the substrate 100, a GaN substrate can be used as a homo-substrate, and a sapphire substrate, a SiC substrate or a Si substrate can be used as a hetero-substrate. However, any type of substrate that can grow a nitride semiconductor layer thereon can be employed. In the case that the SiC substrate is used, the n-side electrode 800 can be formed on the side of the SiC substrate.

The nitride semiconductor layers epitaxially grown on the substrate 100 are grown usually by metal organic chemical vapor deposition (MOCVD).

The buffer layer 200 serves to overcome differences in lattice constant and thermal expansion coefficient between the hetero-substrate 100 and the nitride semiconductor layers. U.S. Pat. No. 5,122,845 discloses a technique of growing an AlN buffer layer with a thickness of 100 to 500 Å on a sapphire substrate at 380 to 800° C. In addition, U.S. Pat. No. 5,290,393 discloses a technique of growing an Al₍ₓ₎Ga₍₁₋ₓ₎N (0≦x<1) buffer layer with a thickness of 10 to 5000 Å on a sapphire substrate at 200 to 900° C. Moreover, PCT Publication No. WO/05/053042 discloses a technique of growing a SiC buffer layer (seed layer) at 600 to 990° C., and growing an In₍ₓ₎Ga₍₁₋ₓ₎N (0<x≦1) thereon. Preferably, it is provided with an undoped GaN layer on the buffer layer 200, prior to growth of the n-type nitride semiconductor layer 300.

In the n-type nitride semiconductor layer 300, at least the n-side electrode 800 formed region (n-type contact layer) is doped with a dopant. Preferably, the n-type contact layer is made of GaN and doped with Si. U.S. Pat. No. 5,733,796 discloses a technique of doping an n-type contact layer at a target doping concentration by adjusting the mixture ratio of Si and other source materials.

The active layer 400 generates light quanta (light) by recombination of electrons and holes. Normally, the active layer 400 contains In₍ₓ₎Ga₍₁₋ₓ₎N (0<x≦1) and has single or multi-quantum well layers.

The p-type nitride semiconductor layer 500 is doped with an appropriate dopant such as Mg, and has p-type conductivity by an activation process. U.S. Pat. No. 5,247,533 discloses a technique of activating a p-type nitride semiconductor layer by electron beam irradiation. Moreover, U.S. Pat. No. 5,306,662 discloses a technique of activating a p-type nitride semiconductor layer by annealing over 400° C. PCT Publication No. WO/05/022655 discloses a technique of endowing a p-type nitride semiconductor layer with p-type conductivity without an activation process, by using ammonia and a hydrazine-based source material together as a nitrogen precursor for growing the p-type nitride semiconductor layer.

The p-side electrode 600 is provided to facilitate current supply to the p-type nitride semiconductor layer 500. U.S. Pat. No. 5,563,422 discloses a technique associated with a light transmitting electrode composed of Ni and Au and formed almost on the entire surface of the p-type nitride semiconductor layer 500 and in ohmic-contact with the p-type nitride semiconductor layer 500. In addition, U.S. Pat. No. 6,515,306 discloses a technique of forming an n-type superlattice layer on a p-type nitride semiconductor layer, and forming a light transmitting electrode made of ITO thereon.

Meanwhile, the p-side electrode 600 can be formed thick not to transmit but to reflect light toward the substrate 100. This technique is called a flip chip called a flip chip technique. U.S. Pat. No. 6,194,743 discloses a technique associated with an electrode structure including an Ag layer with a thickness over 20 nm, a diffusion barrier layer covering the Ag layer, and a bonding layer containing Au and Al, and covering the diffusion barrier layer.

The p-side bonding pad 700 and the n-side electrode 800 are provided for current supply and external wire bonding. U.S. Pat. No. 5,563,422 discloses a technique of forming an n-side electrode with Ti and Al.

In the meantime, the n-type nitride semiconductor layer 300 or the p-type nitride semiconductor layer 500 can be constructed as single or plural layers. Recently, a technology of manufacturing vertical light emitting devices is introduced by separating the substrate 100 from the nitride semiconductor layers using laser technique or wet etching.

FIG. 2 is a view illustrating a light emitting device disclosed in International Publication WO/02/75821, particularly, a process of growing a III-nitride semiconductor layer 220 on a patterned substrate 210. The III-nitride semiconductor layers 220 start to grow on lower and upper surfaces of the patterned substrate 210, respectively, and are brought into contact with each other. The growth of the III-nitride semiconductor layer 220 is accelerated in the contact portions to thereby form a flat surface. The patterned substrate 210 scatters light to improve external quantum efficiency, and reduces crystal defects to improve quality of the III-nitride semiconductor layer 220.

FIG. 3 is a view illustrating examples of a pattern used to form a protrusion. A circle, triangle, quadrangle or hexagon can be used as the pattern. Particularly, the hexagonal pattern has an advantage of increasing an arrangement density of protrusions. Here, when a protrusion is formed to the shape of a pattern by means of dry etching, edges of the pattern are actively etched, so that portions of the protrusion corresponding to the edges of the pattern are etched to be rounded. That results in a problem that the protrusion does not follow the shape of the pattern. Moreover, one side of the protrusion becomes parallel to the opposite side. There is thus a limitation on supplying a scattering surface. In this case, if the arrangement density of protrusions is higher or a protrusion is smaller, a problem may occur in the epitaxial growth, i.e., the mass-productivity of a light emitting device.

### DISCLOSURE

### Technical Problem

Accordingly, the present disclosure has been made to solve the above-described shortcomings occurring in the prior art, and an object of the present disclosure is to provide a III-nitride semiconductor light emitting device which can solve the foregoing problems.

Another object of the present disclosure is to provide a III-nitride semiconductor light emitting device which can improve external quantum efficiency by diversifying angles of side of a scattering protrusion.

Also, another object of the present disclosure is to provide a III-nitride semiconductor light emitting device which can improve mass-productivity, even though it uses a substrate having a scattering protrusion.

Also, another object of the present disclosure is to provide a III-nitride semiconductor light emitting device which can increase an arrangement density of scattering protrusions on a substrate.

### Technical Solution

This section provides a general summary of the disclosure and is not a comprehensive disclosure of its full scope or all of its features.

According to one aspect of the present disclosure, there is provided a III-nitride semiconductor light emitting device comprising: a substrate with a plurality of protrusions formed thereon, each of the plurality of protrusions having three acute portions and three obtuse portions; and a plurality of III-nitride semiconductor layers formed over the substrate and including an active layer for generating light by recombination of electrons and holes.

According to another aspect of the present disclosure, there is provided a III-nitride semiconductor light emitting device comprising: a substrate with a plurality of protrusions formed thereon; and a plurality of III-nitride semiconductor layers formed over the substrate and including an active layer for generating light by recombination of electrons and holes; wherein each of the plurality of protrusions includes a first scattering surface having a first slope and exposed by wet etching, and a second scattering surface having a second slope different from the first slope and formed to be sharp or pointed so as to prevent growth of the plurality of III-nitride semiconductor layers.

Also, according to another aspect of the present disclosure, there is provided a III-nitride semiconductor light emitting device comprising: a sapphire substrate with a plurality of protrusions formed thereon to be aligned in a plurality of arrays, the plurality of arrays being parallel to the flat zone of the sapphire substrate, the plurality of protrusions within one array being alternately arranged to the plurality of protrusions within an adjacent array, and each of the plurality of protrusions having a scattering surface exposed by wet etching; and a plurality of III-nitride semiconductor layers formed over the substrate and including an active layer for generating light by recombination of electrons and holes.

### ADVANTAGEOUS EFFECTS

In accordance with a III-nitride semiconductor light emitting device of the present invention, external quantum efficiency can be improved by diversifying angles of sides of a scattering protrusion.

Also, in accordance with a III-nitride semiconductor light emitting device of the present disclosure, mass-productivity can be improved even though it uses a substrate having a scattering protrusion.

Also, in accordance with a III-nitride semiconductor light emitting device of the present invention, an arrangement density of scattering protrusions on a substrate can be increased.

### DESCRIPTION OF DRAWINGS

FIG. 1 is a view illustrating one example of a conventional III-nitride semiconductor light emitting device.

FIG. 2 is a view illustrating a light emitting device disclosed in International Publication WO/02/75821.

FIG. 3 is a view illustrating examples of a pattern used to form a protrusion.

FIG. 4 is a view illustrating examples of a shape and an arrangement structure of protrusions according to the present disclosure.

FIG. 5 is a view illustrating a scattering effect of protrusions according to the present disclosure.

FIGS. 6 and 7 are photographs showing one example of protrusions according to the present disclosure.

FIG. 8 is a view illustrating a method of forming protrusions according to the present disclosure.

FIG. 9 is a photograph showing another example of protrusions according to the present disclosure.

FIG. 10 is a view illustrating one example of an arrangement structure of protrusions with respect to the flat zone.

FIG. 11 is a view illustrating one example of a III-nitride semiconductor light emitting device according to the present disclosure.

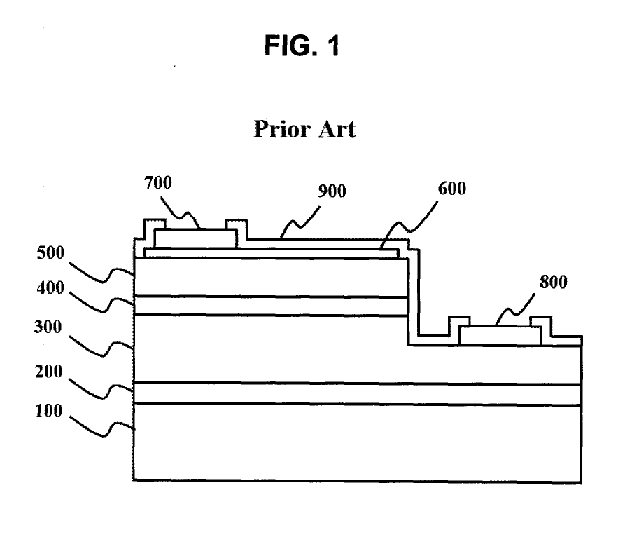

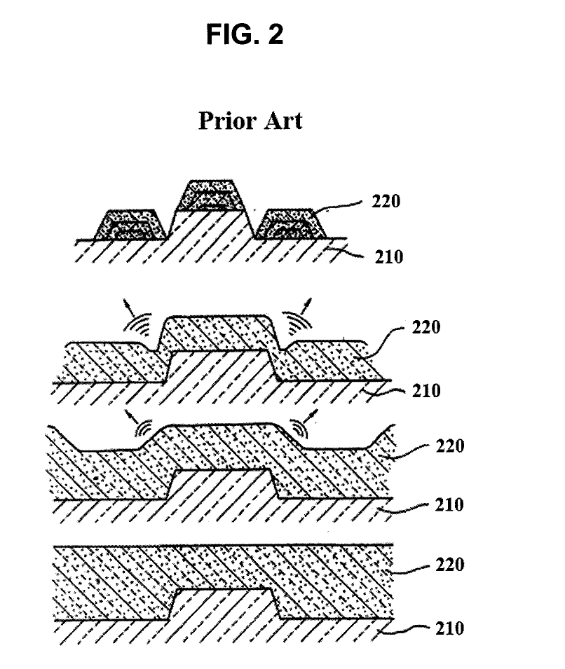

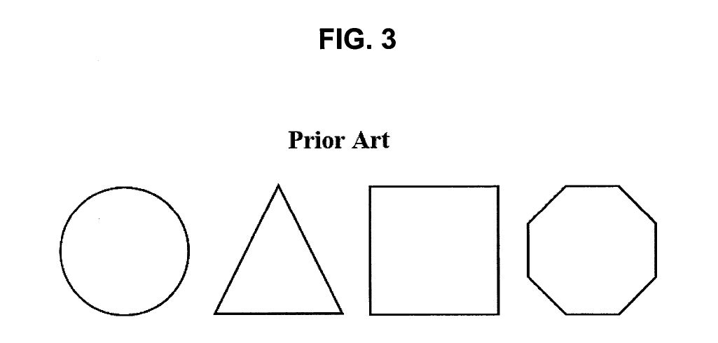

### MODE FOR INVENTION

The present disclosure will now be described in detail with reference to the accompanying drawings.

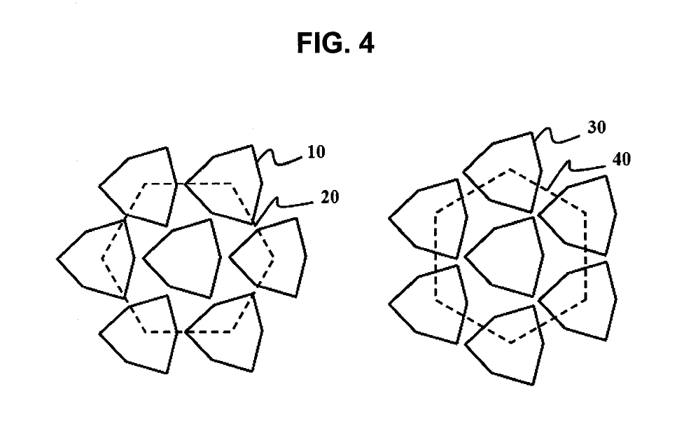

FIG. 4 is a view illustrating examples of a shape and an arrangement structure of protrusions according to the present disclosure. The left side shows protrusions 10 and the most preferable arrangement structure 20 of the protrusions 10 according to the present disclosure, and the right side shows protrusions 30 and another example of an arrangement structure 40 of the protrusions 30 according to the present disclosure. The arrangement structure 20 and the arrangement structure 40 are common in making a hexagon by connecting the centers of the protrusions 10 and the protrusions 30, respectively. However, an area of the protrusions 10 positioned in the arrangement structure 20 is larger than that of the protrusions 30 positioned in the arrangement structure 40. Therefore, an arrangement density of the arrangement structure 20 is higher than that of the arrangement structure 40.

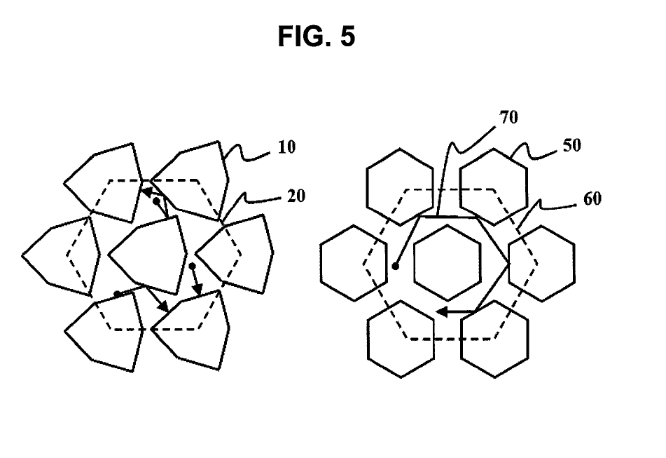

FIG. 5 is a view illustrating a scattering effect of protrusions according to the present disclosure. The left side shows an arrangement structure 20 of protrusions 10 according to the present disclosure, and the right side shows an arrangement structure 60 of dry-etched hexagonal protrusions 50. The arrangement structure 60 of the hexagonal protrusions 50 has a path 70 of rotating and extinguishing light. Meanwhile, in the arrangement structure 20 according to the present disclosure, the protrusions 10 have sides with different angles, so that light can be emitted to the outside of a light emitting device through a short path.

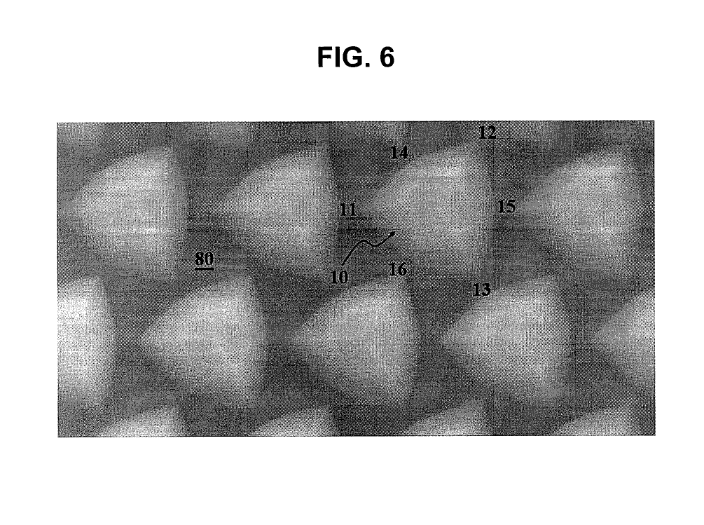

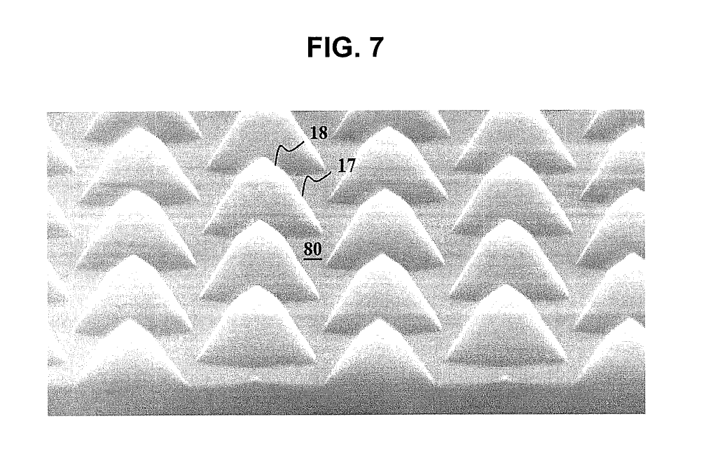

FIGS. 6 and 7 are photographs showing one example of protrusions according to the present disclosure. Protrusion 10 is formed on a bottom surface 80 of a substrate. Protrusion 10 has three acute portions 11, 12 and 13, three obtuse portions 14, 15 and 16, and a scattering surface 17 exposed by wet etching. Preferably, Protrusion 10 has a scattering surface 18 exposed by an additional wet etching. In a case where a flat surface is provided on the upper portion of the protrusion 10, the upper portion may not be covered well by a III-nitride semiconductor layer during the growth, which may generates a pit. Accordingly, the scattering surface 18 not only scatters light but also eliminates the flat surface from the upper portion of the protrusion 10 to restrict generation of the pit.

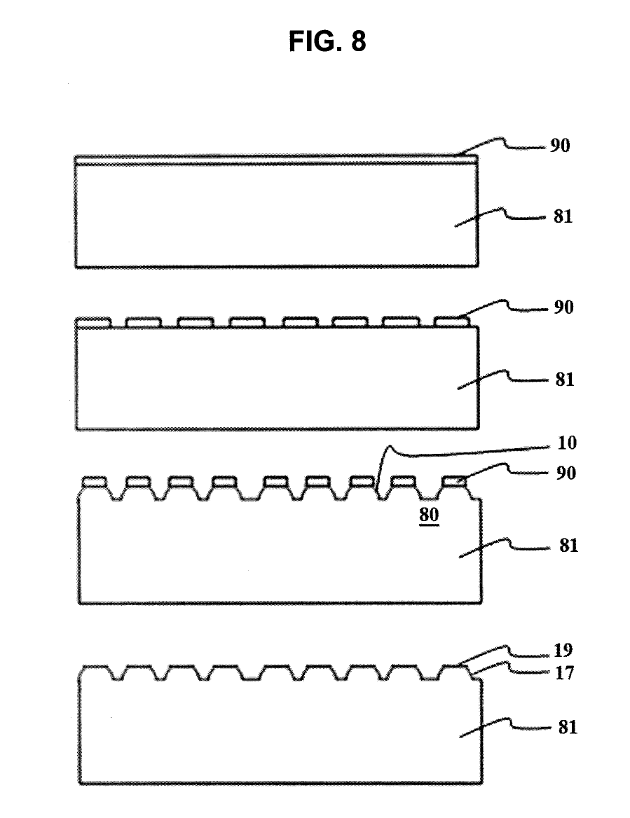

Thereafter, a method of forming protrusions according to the present disclosure will be explained with reference to FIG. 8.

First of all, a substrate 81 is prepared. Then, an SiO₂ film 90 is deposited on the substrate 81 as a mask pattern.

Next, the SiO₂ film 90 is patterned.

Next, wet etching is carried out thereon. The substrate 81 with the SiO₂ film 90 formed thereon is rarely etched. The substrate 81 which does not have the SiO₂ film 90 thereon is etched, so that a bottom surface 80 of the substrate 81 is exposed, forming protrusion 10. Here, the shape of the protrusion 10 can be changed according to a crystal surface of the prepared substrate 81. Detailed conditions for forming the protrusion 10 of FIG. 6 according to the present disclosure will be described later.

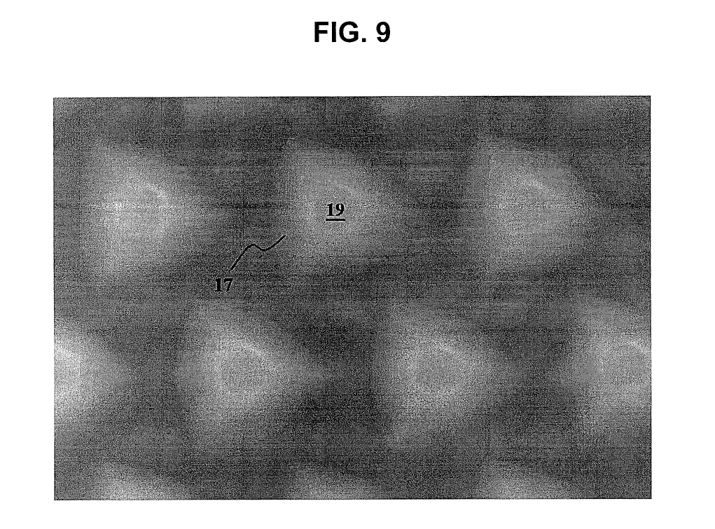

Next, when the SiO₂ film 90 is eliminated, protrusion 10 with a flat top surface 19 and scattering surface 17 is formed. FIG. 9 shows the protrusion with the flat top surface 19 and the scattering surface 17. In the meantime, if the flat top surface 19 does not have a sufficient size to grow a III-nitride semiconductor layer, such a flat top surface 19 can cause a pit to the III-nitride semiconductor layer according to the growth condition of the III-nitride semiconductor layer. Therefore, it is preferable to eliminate the top surface 19 by means of an additional wet etching process. The etching of the protrusion 10 starts from edge of the flat top surface 19 in case of the SiO₂ film 90 not existing, so that the protrusion 10 have a sharp shape.

FIGS. 6 and 7 show the protrusion 10 formed by the above procedure. The protrusion 10 has three acute portions 11, 12 and 13 and three obtuse portions 14, 15 and 16 with various scattering angles, thereby increasing an external emission rate of light (the scattering effect can be improved more than a case that the acute portions are connected by straight lines). In addition, when the protrusion 10 has both scattering surfaces 17 and 18, the protrusion 10 can have different scattering angles to thereby increase an external emission rate of light. Moreover, when a crystal surface of the substrate 81 is fixed, the shape of the protrusions 10 is determined (even if various mask patterns (e.g., circle, ellipse, quadrangle, etc.) are used, the protrusion 10 does not follow the shape of the mask pattern unlike dry etching). Therefore, the present disclosure suggests a method of increasing an arrangement density of the protrusions 10 by changing an arrangement structure in mask pattern (e.g., the SiO₂ film 90), with the shape of the protrusions 10 determined (Because the protrusions by dry etching have the shape of the mask pattern, the arrangement density of the protrusions is not changed whether an array is arranged to be parallel or vertical to the flat zone. Therefore, when the dry etching is carried out, the foregoing problem does not occur.). Further, since edges are rounded during the dry etching, it is difficult to form protrusion 10 with three acute portions 11, 12 and 13 and three obtuse portions 14, 15 and 16. On the contrary, according to the present disclosure, various scattering portions 11 to 16 and surfaces 17 and 18 are formed by the wet etching.

A process of forming protrusion 10 will now be described in detail.

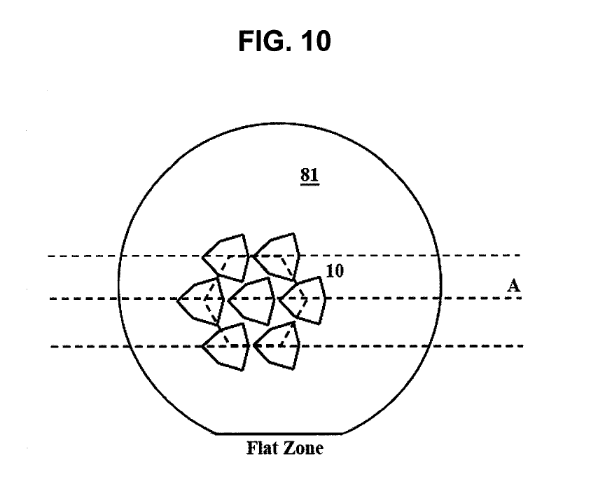

First of all, a sapphire substrate 81 having C surface as a growth surface of a III-nitride semiconductor layer is prepared. Then, an SiO₂ film 90 is deposited thereon at a thickness of 3000 Å. Next, circular patterns with a diameter of 1 μm are patterned on the SiO₂ film 90 at intervals of 3 μm (4 μm from the centers of the patterns). Here, the patterns are aligned in a plurality of arrays A parallel to the flat zone of the sapphire substrate 81. A plurality of protrusions 10 arranged in one array are alternately arranged to a plurality of protrusions arranged in an adjacent array (refer to FIGS. 5, 6 and 10). Next, the sapphire substrate 81 with the SiO₂ film 90 patterned thereon is wet-etched at 280° C. for 11 minutes, using an etching fluid prepared by mixing H₂SO₄ with H₃PO₄ at a ratio of 3:1. Next, the SiO₂ film 90 is removed by a buffered oxide etchant. Next, the sapphire substrate 81 is further wet-etched at 280° C. for 1 minute by the aforementioned etching fluid.

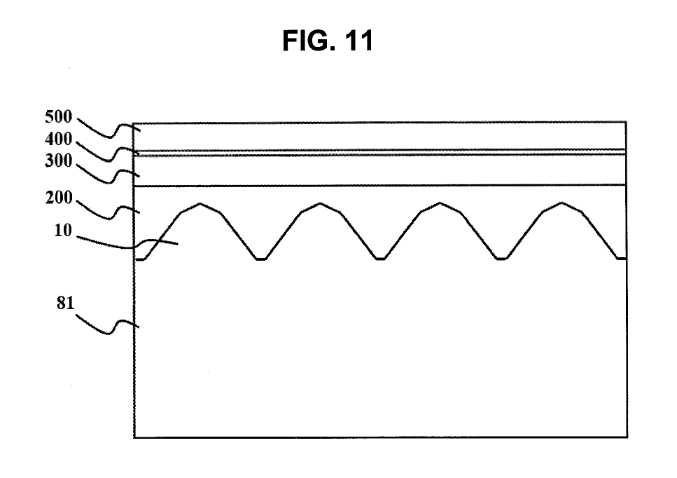

FIG. 11 is a view illustrating one example of a III-nitride semiconductor light emitting device according to the present disclosure. The III-nitride semiconductor light emitting device includes a substrate 81 with protrusion 10 formed thereon, a buffer layer 200, a n-type III-nitride semiconductor layer 300, an active layer 400 for generating light by recombination of electrons and holes, and a p-type III-nitride semiconductor layer 500.

Various embodiments of the present disclosure will be described.

(1) A III-nitride semiconductor light emitting device including a protrusion having a side exposed by wet etching.

(2) A III-nitride semiconductor light emitting device including a protrusion with three acute portions and three obtuse portions.

(3) A III-nitride semiconductor light emitting device including a protrusion with a region formed by a secondary etching so as to reduce pits in a III-nitride semiconductor layer.

(4) A III-nitride semiconductor light emitting device including a substrate where a plurality of protrusions arranged in one array are alternately arranged to a plurality of protrusions arranged in an adjacent array.

1. A III-nitride semiconductor light emitting device comprising:
a substrate having a top surface and a bottom surface;
a plurality of protrusions formed on the top surface of said substrate, each of the plurality of protrusions having three acute angled portions and three obtuse angled portions; and
a plurality of III-nitride semiconductor layers formed over the substrate, the plurality of III-nitride semiconductor layers including an active layer for generating light by recombination of electrons and holes.

2. The III-nitride semiconductor light emitting device of claim 1, wherein each of the plurality of protrusions comprises a light-scattering surface exposed by wet etching.

3. The III-nitride semiconductor light emitting device of claim 2, wherein each of the plurality of protrusions comprises an additional light-scattering surface for preventing pits from being generated on top surfaces of the protrusions and the additional light-scattering surface being formed by wet etching.

4. The III-nitride semiconductor light emitting device of claim 3, wherein the additional light-scattering surface has a different slope from that of the light-scattering surface.

5. The III-nitride semiconductor light emitting device of claim 1, wherein the substrate is a sapphire substrate.

6. The III-nitride semiconductor light emitting device of claim 5, wherein the plurality of III-nitride semiconductor layers are formed over C surface of the sapphire substrate.

7. A III-nitride semiconductor light emitting device comprising:
a substrate having a top surface and a bottom surface;
a plurality of protrusions formed on the top surface of said substrate; and
a plurality of III-nitride semiconductor layers formed over the substrate, the plurality of III-nitride semiconductor layers including an active layer for generating light by recombination of electrons and holes,
wherein each of the plurality of protrusions includes a first light-scattering surface having a first slope and exposed by wet etching, and a second light-scattering surface having a second slope that is different from the first slope and being formed to be sharp so as to prevent growth of the plurality of III-nitride semiconductor layers.

8. The III-nitride semiconductor light emitting device of claim 7, wherein the substrate is a sapphire substrate, and the plurality of III-nitride semiconductor layers are formed over C surface of the sapphire substrate.

9. The III-nitride semiconductor light emitting device of claim 8, wherein the plurality of protrusions are formed to be aligned in a plurality of arrays on the sapphire substrate, and the plurality of arrays are parallel to a flat zone of the sapphire substrate.

10. A III-nitride semiconductor light emitting device comprising:
a sapphire substrate having a top surface and a bottom surface;
a plurality of protrusions formed on the top surface of said substrate to be aligned in a plurality of arrays, the plurality of arrays being parallel to a flat zone of the sapphire substrate, the plurality of protrusions within one array being alternately arranged to the plurality of protrusions within an adjacent array, and each of the plurality of protrusions having a light-scattering surface exposed by wet etching; and
a plurality of III-nitride semiconductor layers formed over the substrate and the plurality of III-nitride semiconductor layers including an active layer for generating light by recombination of electrons and holes.

11. The III-nitride semiconductor light emitting device of claim 10, wherein each of the plurality of protrusions comprises an additional light-scattering surface for preventing pits from being generated on top surfaces of the protrusions and the additional light-scattering surface being formed by wet etching.

12. The III-nitride semiconductor light emitting device of claim 11, wherein each of the plurality of protrusions comprises three acute angled portions and three obtuse angled portions.

13. The III-nitride semiconductor light emitting device of claim 12, wherein the plurality of III-nitride semiconductor layers are formed over C surface of the sapphire substrate.
